(19) United States
(12) Patent Application Publication
(10) Pub. No.: US 2024/0302752 A1
(43) Pub. Date: Sep. 12, 2024

(54) POST-OVERLAY COMPENSATION ON LARGE-FIELD PACKAGING

(71) Applicant: Onto Innovation Inc., Wilmington, MA (US)

(72) Inventors: Yin-Yi John Chang, Taichung (TW); Ting-Jia Timothy Chang, Wilmington, MA (US); Jian Lu, Wilmington, MA (US)

(21) Appl. No.: 18/548,515

(22) PCT Filed: Mar. 1, 2022
(86) PCT No.: PCT/US2022/018385

§ 371 Date: Aug. 31, 2023

Related U.S. Application Data
(60) Provisional application No. 63/155,262, filed on Mar. 1, 2021.

(51) Int. Cl. G03F 7/00

(52) U.S. Cl. CPC G03F 7/70633; G03F 7/705; G03F 7/70791

(57) ABSTRACT

A lithography challenge for large heterogeneous integration of integrated circuit devices is the limited size of the exposure field (typically 60 mm×60 mm or smaller) for most currently available lithography systems, Smaller-field systems can be used to pattern large substrates (e.g., panels) by stitching together multiple exposure fields. However, the stitching of exposure fields affects both productivity and yield because of the need for multiple exposures, which includes multiple reticles, and a risk of alignment errors at the stitching boundaries, A large-exposure field eliminates these problems associated with smaller exposure fields. However, there are also challenges associated with a large-exposure field, such as exposing onto a possibly warped or distorted panel. Various examples disclosed herein include a post-overlay compensation method that use an overlay-model prior to exposing the panel to reduce or eliminate errors due to the warped, or distorted panel. Other methods and systems are also disclosed.

### CLAIM OF PRIORITY

This application claims the benefit of priority to U.S. Provisional Patent Application Ser. No. 63/155,262, filed on 1 Mar. 2021, and entitled “EXTREMELY LARGE EXPOSURE FIELD WITH FINE RESOLUTION LITHOGRAPHY TECHNOLOGY TO ENABLE NEXT GENERATION PANEL LEVEL ADVANCED PACKAGING,” which is incorporated herein by reference in its entirety.

### TECHNOLOGY FIELD

The disclosed subject matter is related generally to the field of lithography and metrology tools used in the semiconductor and allied industries (e.g., flat-panel display and solar-cell production facilities). More specifically, in various embodiments, the disclosed subject matter is related to a method of correcting overlay and alignment issues on a warped or distorted panel.

### BACKGROUND

Many contemporary advanced electronic device systems integrate multiple integrated circuit (IC) dice, with each die being optimized for a specific capability and fabricated with a process designed specifically for that type of circuit. These oftentimes disparate IC dice are then coupled (e.g., electrically) to each other using heterogeneous integration processes.

One example of heterogeneous integration uses advanced IC substrates (AICS) in a process known as ultra-high density fan-out panel-level process (FOPLP). The FOPLP uses redistribution lines (RDLs) where many layers of patterned conductive and insulating materials are processed on both sides of a large panel to route electrical signals between a number of IC dice. Once the RDL layers are completed, connection points are formed to connect with pads on each of the IC dice.

The lithography challenge for large heterogeneous integration is the limited size of the exposure field (typically 60 mm×60 mm or smaller) for most currently available lithography systems. Smaller-field systems can be used to pattern large substrates by stitching together multiple exposure fields. However, the stitching of exposure fields affects both productivity and yield because of the need for multiple exposures, which includes multiple reticles, and the risk of errors at the stitching boundaries (e.g., alignment errors). A large-exposure field eliminates these problems associated with smaller exposure fields.

However, there are also challenges associated with a large-exposure field. These challenges include photolithographically projecting a reticle onto a panel that may be warped and/or otherwise distorted due to forces created from the multiple layers formed on the panels. A post-overlay compensation method disclosed herein uses an overlay-model prior to exposing the substrate to reduce or eliminate errors due to the warped or distorted panel.

### SUMMARY

In various embodiments, the disclosed subject matter is a method for analyzing and correcting for pattern distortion in a panel during a lithography operation on the panel. The method includes determining an optical model to be applied to correct for distortion in the panel. The determination of the optical model includes making a determination of potential differences when exposing on the panel in at least one of magnification correction and anamorphic correction from a number of patterns on a reticle as compared with planned features on respective ones of the number of patterns. The at least one of the magnification correction and the anamorphic correction to be applied to an exposure field during a photolithographic exposure on the panel. The method further includes determining correction data from the determined optical model for applying to the lithography operation and applying the correction data to a global zone of the exposure field. The correction data within the global zone including corrections from each of the number of patterns on the reticle within the exposure field. The exposure field is then photolithographically exposed by the lithography tool in a single shot.

In various embodiments, the disclosed subject matter is a system to analyze and correct for pattern distortion in a panel during a lithography operation on the panel. The system includes one or more hardware-based computational engines to determine an optical model to be applied to correct for distortion in the panel. The determination of the optical model includes collecting metrology-based measurement data from the panel, comparing alignment data supplied by a lithography tool used to expose the panel, and making a determination of measured potential differences in at least one of magnification correction and anamorphic correction from a number of patterns on the reticle as compared with measurements of planned features on respective ones of the number of patterns. The at least one of magnification correction and anamorphic correction to be applied optically to an exposure field during a photolithographic exposure. Correction data are determined from the determined optical model to apply to the lithography operation. A memory is coupled to the one or more hardware-based computational engines to store results from the determination of the optical model. The lithography tool is to apply the correction data received from the memory to a global zone within the exposure field where the correction data within the global zone includes corrections from each of the number of patterns on the reticle within the exposure field. The lithography tool photolithographically exposes the exposure field in a single shot.

In various embodiments, the disclosed subject matter is a method for analyzing and correcting for pattern distortion in a panel during a lithography operation on the panel, the method includes determining an optical model to be applied to correct for distortion in the panel. The determination of the optical model includes collecting metrology-based measurement data from the panel, comparing alignment data supplied by a lithography tool used to expose the panel, making a determination of measured potential differences in at least one of magnification correction and anamorphic correction from a number of patterns on the reticle as compared with measurements of planned features on respective ones of the number of patterns. The at least one of magnification correction and anamorphic correction to be applied optically to an exposure field during a photolithographic exposure. The method further includes determining correction data from the determined optical model to apply to the lithography operation and applying the correction data to a global zone within the exposure field. The correction data within the global zone including corrections from each of the number of patterns on the reticle within the exposure field. The exposure field is then photolithographically exposed by the lithography tool in a single shot.

In various embodiments, the disclosed subject matter is a machine-readable medium including instructions that, when executed by one or more processors of a machine, cause the machine to perform operations. The operations include determining an optical model to be applied to correct for distortion in the panel. The determination of the optical model includes making a determination of potential differences when exposing on the panel in at least one of magnification correction and anamorphic correction from a number of patterns on a reticle as compared with planned features on respective ones of the number of patterns. The at least one of the magnification correction and the anamorphic correction to be applied to an exposure field during a photolithographic exposure on the panel. The method further includes determining correction data from the determined optical model for applying to the lithography operation and applying the correction data to a global zone of the exposure field. The correction data within the global zone including corrections from each of the number of patterns on the reticle within the exposure field. The exposure field is then photolithographically exposed by the lithography tool in a single shot.

### BRIEF DESCRIPTION OF FIGURES

Various ones of the appended drawings merely illustrate example implementations of the present disclosure and should not be considered as limiting its scope.

FIG. 1A shows an example of a number of exposure fields on a 300 mm round substrate;

FIG. 1B shows an example of a number of exposure fields on a 515 mm×510 mm panel, as is often used in advanced packaging techniques;

FIG. 2 shows an example of a large-exposure field layout superimposed over the panel of FIG. 1B;

FIG. 3 shows an example of a cross-section of a portion of a panel including redistribution layers (RDLs) used to electrically couple integrated circuit dice to each other in a fanout panel-level packaging technique;

FIG. 4 shows an example of a portion of a lithography-tool vector map that is used in accordance with various embodiments disclosed herein for post-overlay compensation on large-field packaging;

FIGS. 5A through 5C show a number of types of exposure-field correction types that may be applied to the large-exposure field layout prior to exposing a portion of the panel;

FIG. 6A shows an example of an original overlay result, layer-to-layer, prior to applying the exposure-field correction types of FIGS. 5A through 5C;

FIG. 6B shows an example of a post-overlay compensation result, layer-to-layer, after applying selected ones of the exposure-field correction types of FIGS. 5A through 5C;

FIG. 7 shows a simplified example of a lithography tool and components to which the exposure-field correction types of FIGS. 5A through 5C may be applied to produce magnification corrections and anamorphic corrections;

FIG. 8 shows an example of a post-overlay compensation working-method flow; and

FIG. 9 shows a block diagram of an example comprising a machine upon which any one or more of the techniques (e.g., methodologies) discussed herein may be performed.

### DETAILED DESCRIPTION

A typical advanced integrated circuit substrates (AICS) process stack includes multiple layers. Each layer uses a lithography process to build up a desired pattern. Currently, AICS lithography yield criteria is from approximately 95% to 97%. Consequently, There is about a 3% to 5% yield loss in lithography per layer. In a six-layer stack process, the loss in final yield by lithography will be from about 16% to 27%. This high yield loss will continue to increase based on a higher density of circuits, reduced sizes of printed features in each layer of the AICS process, and more layers in the future. A large portion of the yield loss is due to overlay and alignment errors from one layer to a subsequently exposed layer.

To address alignment errors, additional corrections are proposed io increase yield due to overlay and alignment errors. For example, a post-overlay compensation machine-learning (POC ML) algorithm can be used to predict the overlay results using various types of corrections. The POC ML algorithm can be used to analyze the correctable terms based on current overlay errors, such as translation, rotation, scale, magnification and orthogonality. The overlay errors may be corrected by either isotropic-magnification correction or anisotropic (anamorphic) correction. The overlay errors may be determined by using at least one of actual metrology-based measurements (combined with alignment data from the lithography tool) and collected overlay-data. The overlay data can be used to determine predictions regarding the final overlay results and develop an optical overlay-model.

A photolithography tool (e.g., a lithography tool such as a photolithographic stepper) is then corrected using the optical overlay-model prior to exposing the substrate. The corrections may be performed by adjusting at least one physical component of the photolithography tool. The adjustments can include adjusting at least one of the reticle stage relative to the optical system of the photolithography tool, adjusting the reticle stage relative to the substrate (e.g., panel) stage of the photolithography tool, and adjusting the optical system of the photolithography tool relative to the substrate stage.

In order to couple electrically a number of integrated circuit (IC) dice on a panel, various types of fan-out panel-level process (FOPLP) techniques involve forming a number of redistribution layers (RDLs) onto a large panel. In one example, the panels are 510 mm×515 mm in size. The RDLs allow selected pins on an IC die to be electrically coupled to selected pins on other ones of the IC dice.

A large-field lithography system can expose, for example, a 250 mm×250 mm exposure field in a single shot on a panel without stitching. However, as noted above, a large exposure field may make layer-to-layer alignment of features on the panel difficult due to the potential warpage and distortion of the panels.

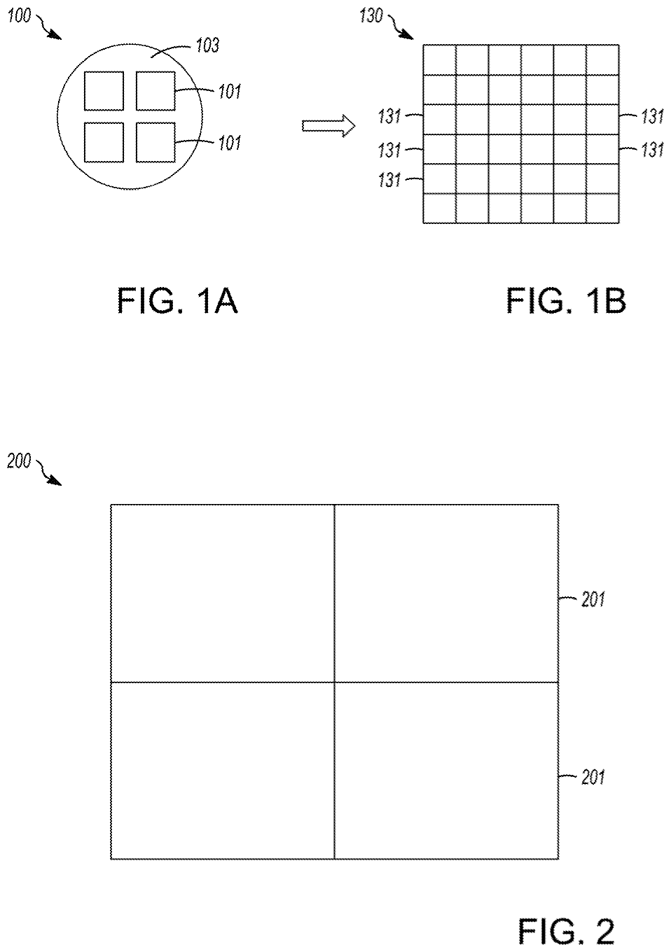

With reference now to FIG. 1A, an example 100 of a number of exposure fields 101 exposed on a round substrate 103 is shown. The round substrate 103 may comprise, for example, a 300 mm wafer. In this example, there are only four exposure fields 101 on the round substrate 103. Each of the exposure fields 101 represents an exposure field having a size of 80 mm×80 mm.

In comparison with FIG. 1A, FIG. 1B shows an example of a number of exposure fields 131 on a panel 130. The panel 130 may comprise, for example, a 515 mm×510 mm panel. Such a panel may form a base material for additional layers, as described below. The panel base material often consists of a copper-clad laminate (CCL), a glass-reinforce epoxy laminate material such as FR-4, composite materials, glass, or other substrates as are often used in advanced packaging techniques. Due to the size and shape, the panel 130 can accommodate far more exposure fields, along with a concomitant increase in the number of IC dice that may be formed on the package, as compared with the example 100 with the exposure fields 101 formed on the substrate 103.

FIG. 2 shows an example of a large-exposure field layout 200 superimposed over the panel 130 of FIG. 1B. Each of the exposure fields 201 shown are significantly larger than the exposure fields 101, 131 of FIGS. 1A and 1B. In various embodiments, the exposure fields 201 may have a physical size of 250 mm×250 mm. However, this 250 mm×250 mm size is used for illustration purposes only and other sizes can be used.

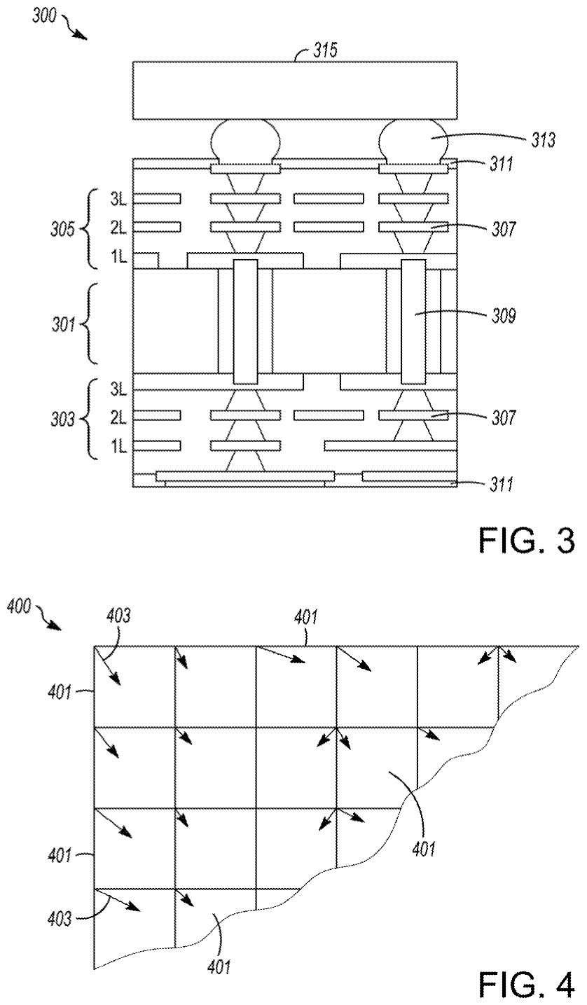

In comparison with the substantially larger exposure field of the example of 250 mm×250 mm, the 80 mm×80 mm exposure field sizes requires a significantly larger number of steps (exposures) to cover the panel. In some conventional panel-exposure stepping systems, the exposure field may only be 59 mm×59 mm. For these examples, there are only four steps to cover the panel with the 250 mm×250 mm exposure field size versus 36 steps for the 80 mm×80 mm exposure field size and 64 steps for the 80 mm×80 mm exposure field size. Consequently, there are from nine times to 16 times as many steps required for the smaller exposure fields. Each time the lithography tool (e.g., a stepper) moves a reticle to a new exposure location, the number of potential stepping errors results in an increase in stitching errors. Each of these errors is compounded when each exposure location involves several reticles-one reticle to cover each layer. As given as an example below with reference to FIG. 3, there can be six or more layers per panel. Further, there is a fixed amount of time required for the lithography tool to step and settle at each new exposure location.

FIG. 3 shows an example of a cross-section of a portion of a panel 300 including redistribution layers (RDLs) that include inter-layer conduction pads 307 (metal pads or micro-vias) coupled in predefined ways by electrical interconnects (metal traces). The RDLs are used to reroute electrical connection points by fanning out and electrically connecting integrated circuit dice to each other in a fanout panel-level packaging (FOPLP) technique. In this example, a panel core 301 (e.g., a copper-clad laminate (CCL) base panel) is shown to include an upper-level 305 of layers and a lower-level 303 of layers. The upper-level 305 of layers and the lower-level 303 of layers each contain three layers and are formed on opposing sides of the panel core 301.

The panel core 301 is further shown to include a via 309 (also referred to as a through-substrate via (TSV) or a plated through-hole (PTH)). The via 309 may be, for example, a laser-drilled hole through the panel core 301 and may be filled or plated internally with a conductive material, such as copper (Cu) or tungsten (W). The via 309 therefore serves to provide an electrical connection from one side of the panel core 301 to the other. The via 309 also provides a target position to which the subsequent layers formed on the panel core 301 may be aligned. As shown, each of the three layers in the upper-level 305 of layers and the lower-level 303 of layers include a number of inter-layer conduction pads 307 to which subsequent layers may be electrically connected. The inter-layer conduction pads 307 are coupled to remaining portions of the RDL (electrical interconnects or electrical traces) formed between selected ones of the inter-layer conduction pads 307 on a given layer.

The inter-layer conduction pads 307 electrically connect one layer with adjoining layers. Therefore, during formation and exposure of the RDLs, each layer is substantially aligned with a previous layer. To preserve yield within an AICS panel, the inter-layer conduction pads 307 on a subsequently formed layer overlays and registers with selected underlying ones of the inter-layer conduction pads 307. Any warpage or other distortion in the panel 300 upon which the layers are formed can make a precise and accurate overlay from one layer to the next layer difficult. Consequently, the disclosed subject matter compensates for the warpages or other distortions in the panel, thereby allowing a larger exposure field while still increasing an overall yield of the packaged devices.

At an uppermost portion of the panel 300, a dielectric film 311 can be formed over the RDL lines to electrically isolate the metal conductors. Finally, an integrated circuit device 315 (a “chip”) is electrically connected by conductive connection-points 313 to the underlying RDLs. The integrated circuit devices can also be connected to the lower-level 303 of layers (not shown in FIG. 3 for clarity).

The conductive connection-points 313 may comprise electrically-conductive-connection technologies such as solder bumps, controlled-collapse chip connections (C4), underbump metallization (UBM) with a copper pillar and a solder cap, and other conductive-connection technologies known in the relevant art.

Table I shows a comparison of an original yield based on the number of layers compared with an improved yield using techniques of the disclosed subject matter provided herein. For example, using an assumed value of an original yield of 97% per layer and an assumed value of an improved yield of 98% per layer, or only 1% difference per layer, one can see that the overall increase in yield is 5.29% for a six-layer panel. The improved yield is a direct result of the techniques disclosed herein.

TABLE I

| | | | | | | OVERALL YIELD | |
|---|---|---|---|---|---|---|---|
| ORIGINAL YIELD | | | IMPROVED YIELD | | | INCREASE | |
| | | YIELD | | | YIELD | | YIELD |
| LAYER | YIELD | LOSS | LAYER | YIELD | LOSS | LAYER | INCREASE |
| 1 | 97.00% | 3.00% | 1 | 98.00% | 2.00% | 1 | 1.00% |
| 2 | 94.09% | 5.91% | 2 | 96.04% | 3.96% | 2 | 1.95% |
| 3 | 91.27% | 8.73% | 3 | 94.12% | 5.88% | 3 | 2.85% |
| 4 | 88.53% | 11.47% | 4 | 92.24% | 7.76% | 4 | 3.71% |
| 5 | 85.87% | 14.13% | 5 | 90.39% | 9.61% | 5 | 4.52% |
| 6 | 83.30% | 16.70% | 6 | 88.58% | 11.42% | 6 | 5.29% |
| 7 | 80.80% | 19.20% | 7 | 86.81% | 13.19% | 7 | 6.01% |
| 8 | 78.37% | 21.63% | 8 | 85.08% | 14.92% | 8 | 6.70% |

Therefore, as indicated by Table I, an overall yield increase of only 1% per layer results in a significant overall increase in yield.

The yield loss indicated in Table I is related to an assumed yield being constant per layer. The assumed yield is then raised to the power of the layer according to the following equation:

$${Y}_{l} = 1 - {Y}_{p l}^{n}$$

where Yₗ is the yield loss, Yₚₗ is the yield per layer, and n is the number of layers. Since a density of devices formed on a panel will continue to increase, stitching errors will continually increase with increased device densities unless the industry begins using increased exposure-field sizes. However, as noted above, the increased size of exposure fields can be affected by distortions and warpage in the panels upon which such fields are exposed. Consequently, the disclosed techniques provided herein become increasingly important.

With continuing reference to FIG. 3, AICS FOPLP techniques often employ the via 309 as a target. The via 309 is commonly formed by laser-drilling operations. Unfortunately, laser-drilling operations have low accuracy capability and poor shape control of the drilled mark. In addition to the panel warpage and distortion issues, these additional laser-mark formation issues also lead to an inaccurate alignment solution, thereby complicating subsequent overlay alignment in the lithography process. Therefore, to minimize or eliminate the overlay alignment issues, an alignment offset or correction is used.

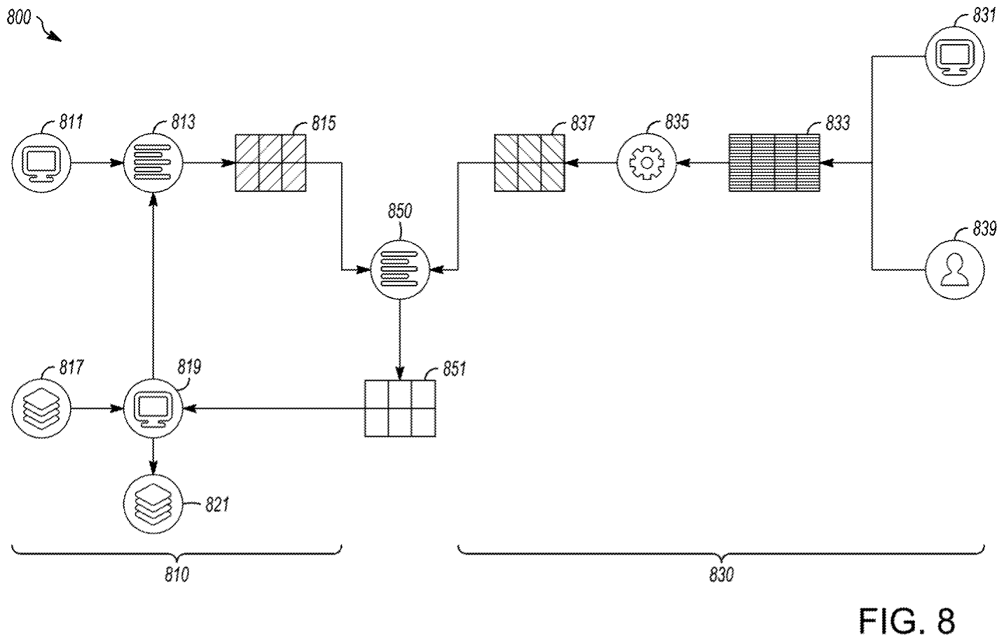

FIG. 4 shows an example of a portion of a lithography-tool vector map 400 that is used in accordance with various embodiments disclosed herein for post-overlay compensation on large-field packaging. As described in more detail below with reference to FIG. 8, the lithography-tool vector map 400 may be produced by metrology-based measurements of alignment errors, by comparison with historical databases of prior AICS panel formation from similar processes, or be a combination of metrology-based measurements combined with the comparison with historical databases.

FIG. 4 is shown to include a number of vectors 403 placed within a defined location, such as a field 401, on a reticle. The field 401 can be considered as including a plurality of patterns to be exposed on the panel. The field 401 can be, for example, an individual die field to be projected onto a panel. The vectors 403 within FIG. 4 are merely examples. In various embodiments, the origin (tail) of the vector can be located anywhere within the fields 401. For example, rather than having the origin in the upper corner or corners of the fields 401 as shown, the origin of each of the vectors 403 can be selected to be at the center of the field 401. Also, more than one vector can be placed within the fields 401 to account for skew variations, anamorphic distortions, scaling variations, or other variations.

The placement and layout of the lithography-tool vector map 400 of FIG. 4 is therefore shown merely as an example. For example, an actual reticle on which each of the fields 401 is formed often contains multiple sizes and shapes of fields.

Each of the fields 401 contains a number of features, including patterns of vias and redistribution lines (electrical traces) which are later photolithographically projected on the panel. The feature sizes typically range from a few micrometers to tens of micrometers. Consequently, the small feature sizes depend on accurate overlay registration and alignment among the multiple vias and distribution layers that are built up to form the RDL. Lacking accurate overlay registration and alignment can lead to a loss in yield.

Alignment errors can be measured in situ on the lithography tool or on an external metrology system. These measurement tools compile metrology datasets to determine the displacement of each field. These metrology data are then converted into a correction file that is sent to the lithography tool (e.g., a stepper). The metrology data can include, for example, translational and rotational placement errors. In embodiments, a position of each field is measured before each exposure in the lithography system to ensure sufficient registration with the underlying layer. In various embodiments, a software engine can be used to analyze the displacement errors to predict yield. The yield may be based on a user-designated limit for an acceptable, pre-determined, registration error. As noted above, each of these techniques is discussed in more detail with regard to FIG. 8, below.

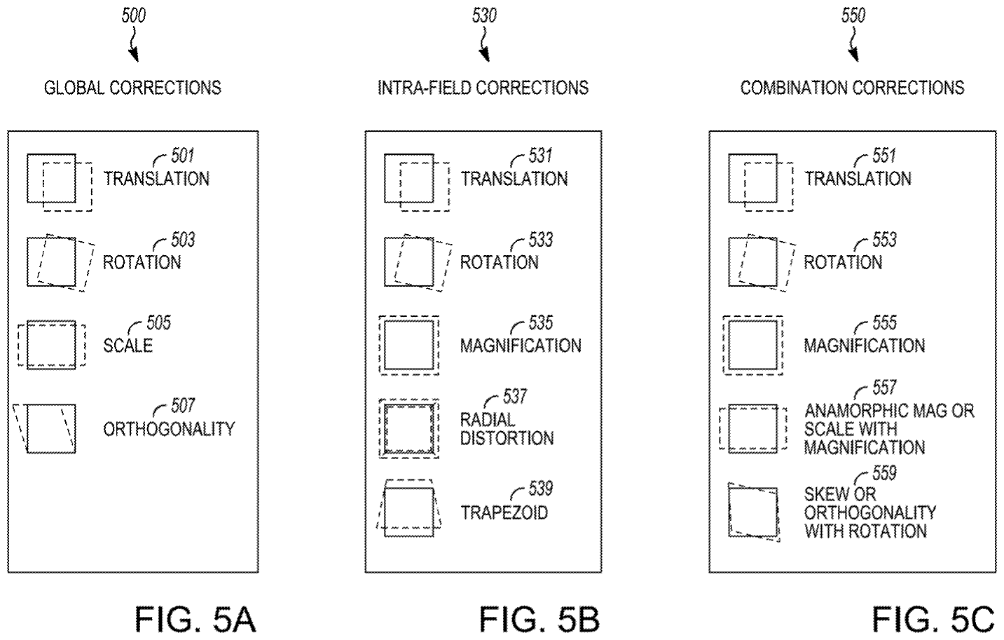

Once the lithography-tool vector map 400 of FIG. 4 is prepared, FIGS. 5A through 5C show a number of types of exposure-field correction types that are determined from the lithography-tool vector map 400. The exposure-field correction types may be determined for individual fields, and then combined for an overlay solution of a large-exposure field layout prior to exposing a portion of the panel. The correction types shown are based on an example of how a square field (e.g., a die) may need to be re-positioned or re-shaped to account for warpage and other distortions within a panel. To aid in an understanding of the exposure-field correction types, magnification corrections can be used to isotropically enlarge or shrink an apparent size of a pattern on the reticle. Anamorphic corrections can be used to anisotropically enlarge or shrink an apparent size of a pattern on the reticle. Any of the correction types can be used to correct for overlay or registration errors on a warped or distorted panel.

Once any desired corrections are determined, a machine-learning algorithm may be used to calculate an optimization overlay-model based on an alignment solution determined by the desired corrections. The optimization overlay-model is then transferred to the lithography tool to be used when exposing the panel to ensure improved overlay results for each layer.

For example, FIG. 5A shows global corrections 500. The global corrections 500 are shown to include translational corrections 501, rotational corrections 503, scaling corrections 505, and orthogonality corrections 507.

FIG. 5B shows intra-field corrections 530. The intra-field corrections 530 are shown to include translational corrections 531, rotational corrections 533, magnification corrections 535, radial-distortion corrections 537, and trapezoidal corrections 539.

FIG. 5C shows combination corrections 550. The combination corrections 550 are shown to include translational corrections 551, rotational corrections 553, magnification corrections 555, anamorphic magnification or scaling with magnification corrections 557, and skew or orthogonality with rotational corrections 559. The global corrections 500 and the intra-field corrections 530 may be combined to produce the combination corrections 550.

Each of the exposure-field correction types of FIGS. 5A through 5C are provided as examples only. Only one or more of the exposure-field correction types may need to be applied where such corrections are required. Also, based on upon reading and understanding the disclosed subject matter, a person of ordinary skill in the art may determine that other correction types may be used. Examples of other correction types include pin-cushion distortion of a feature and barrel distortion of a feature. Such additional correction types are considered as being within a scope of this disclosure.

Once desired correction types are determined, a table including the type of error and an associated desired correctional value may be prepared. An example of such a table is shown in Table II, below. The numbers in the table are examples only and represent coefficients used in equations of an algorithm that describes a fit for each correction term.

TABLE II

| CORRECTION TERM | VALUE [PPM] |
|---|---|
| X-TRANSLATION | −1.76E−03 |
| X-TRANSLATION | +5.97E−04 |
| MAGNIFICATION | −3.06E−06 |
| ANAMORPHIC | −3.06E−06 |
| MAGNIFICATION | |
| ROTATION | +1.20E−05 |
| SKEW | +1.20E−05 |
| X-TRAPAZOIDAL | +1.67E−07 |
| Y-TRAPAZOIDAL | −6.28E−08 |

Since individual portions (fields) of a single reticle cannot be adjusted with respect to the panel during exposure individually, the correction terms from each field (a zone-solution correction) can then be combined and used to determine a global-solution correction for the entire reticle. The adjustments can be used to adjust at least one of the reticle stage relative to the optical system of the lithography tool, adjusting the reticle stage relative to the substrate stage of the lithography tool, and/or adjusting the optical system of the lithography tool relative to the substrate stage.

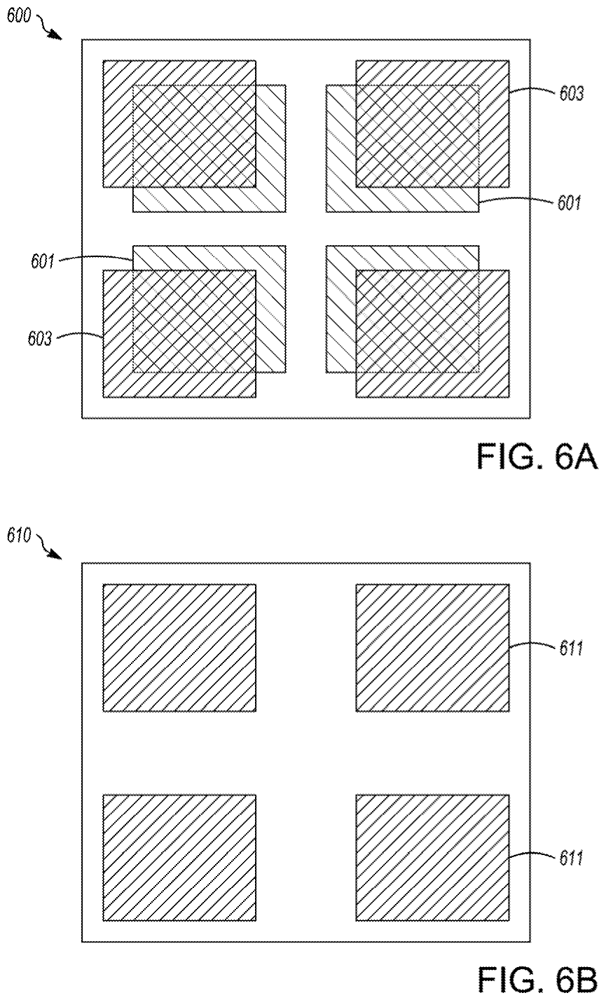

FIG. 6A shows an example of an original overlay result 600, layer-to-layer, prior to applying the exposure-field correction types of FIGS. 5A through 5C. As shown, features 603 are patterned over features 601 on a prior layer. In this example, there is a significant error in translation with poor overlay.

FIG. 6B shows an example of a post-overlay compensation result 610, layer-to-layer, after applying selected ones of the exposure-field correction types of FIGS. 5A through 5C. As shown, features 611 are patterned over features (not shown since covered by features 611) on a prior layer. In this example, there is little to no overlay error.

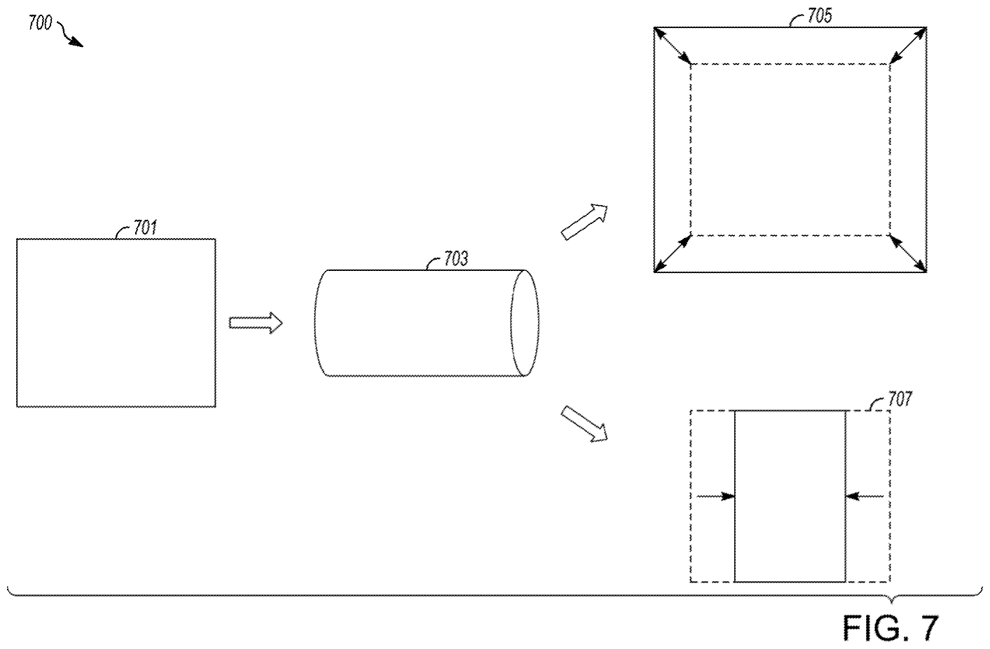

FIG. 7 shows a simplified example of a lithography tool and components to which the exposure-field correction types of FIGS. 5A through 5C may be applied to produce magnification corrections and anamorphic corrections. FIG. 7 is shown to include a reticle 701 in the object plane, an optical system 703 of the lithography tool, an image 705 which has magnification applied, and an image 707 which has anamorphic magnification applied. Each of the images are projected onto a panel held by a panel stage. The image 705, which has magnification applied, and the image 707, which has anamorphic magnification, were produced by applying the techniques described in, for example, FIGS. 4 and 5, to vary a size and/or shape of the exposed image area.

The object plane (the reticle 701) may physically be, for example, shifted, rotated, or tilted (e.g., to accomplish anamorphic corrections) with reference to the optical system 703 based on the correction parameters supplied to the lithography tool. Similarly, the object plane may physically be shifted, rotated, or tilted with reference to a stage holding the panel. The optical system may physically be shifted or tilted with reference to either the object plane or the panel stage. Any one or more of these physical adjustments may be applied prior to exposing the panel based on applying selected ones of the exposure-field correction types of FIGS. 5A through 5C to the lithography tool.

FIG. 8 shows an example of a post-overlay compensation working-method flow 800. The working-method flow 800 is generally shown divided into two portions, each portion being arranged to determine an optical model to be applied to correct for distortion in a panel. The two portions including a metrology-based correction flow 810 and an overlay-database correction flow 830. In various embodiments, one or both of the optical models may be used to provide corrections of an entirety of the reticle (a global zone) to a lithography tool 819.

FIG. 8 is shown to include a substrate supply 817, which may comprise a number of panels onto which patterns are to be exposed by the lithography tool 819 and patterned. A physical output from the lithography tool 819 is exposed substrates 821.

FIG. 8 is further shown to include a metrology-based inspection tool 811, which can supply data to a first computational engine 813. The metrology-based inspection tool 811 may comprise one or more of a variety of optically-based inspection tools, profilometers (including critical-dimension (CD) scanning-electron microscopes (SEMs)), or other metrology tools known in the art. The lithography tool 819 may also supply alignment data (e.g., a mapping file) to the first computational engine 813.

The first computational engine 813 combines data received from both the metrology-based inspection tool 811 and the alignment data from the lithography tool 819, combined with a table including the type of error and an associated desired correctional value as discussed above with reference to FIGS. 4 and 5, to prepare an overlay-data model based on output results from the first computational engine 813. The overlay-data model (a first-overlay model in some embodiments) is stored in a first overlay-model module 815. In an embodiment, the overlay-data model stored in the first overlay-model module 815 may be provided to a second computational engine 850. Alternatively, the first overlay-model module 815 may provide the overlay-data model directly to the lithography tool 819. The second computational engine 850 (which may be a portion of or combined with the first computational engine 813) determines a post-optimization overlay model.

In the overlay-database correction flow 830 portion of FIG. 8, a user 839 can supply historical or test overlay results to an overlay data database 833. Additional overlay results may be gleaned from prior measurements provided by a second metrology-based tool 831. A third computational engine 835 (which may be a portion of or combined with the first computational engine 813 and/or the second computational engine 850) processes the overlay results and determines a second overlay model, which may be stored in a second overlay-model module 837.

In an embodiment, the second computational engine 850 combines the overlay-data models and the alignment data from the lithography tool 819 to be used to expose the panel in a single shot of the entire exposure field (e.g., a 250 mm×250 mm field). The second computational engine 850 may then simulate various scenarios to determine a desired result and generate an optimized overlay-model. The optimized overlay-model is provided to the lithography tool 819 to improve overlay and registration of each exposure at each level onto the panel. The optimized overlay model includes parameters to affect at least one of the physical changes to the reticle stage, the substrate stage, and/or the optical system.

A person of ordinary skill in the art will recognize that the various storage modules described above with reference to FIG. 8 are provided merely as an aid in understanding the disclosed subject matter. Data from the modules may flow directly into one or more of the various computational engines without first being stored in a storage module.

A more generalized optimized-lithography exposure loop can be considered to include: (1) measurement of field (die) displacement errors by a metrology tool external to the lithography tool; (2) correction calculations and yield modeling; and (3) exposure of each reticle onto the panel. This optimized-lithography exposure loop can also include continuous run-to-run adjustments.

An advanced lithography tool can accept the externally generated corrections for translation, rotation, tilt, and magnification provided by the optimized overlay-model. For example, advanced lithography tools typically possess a ±1 μm overlay capability with linear (e.g., x-y) magnification compensation, radial magnification compensation, and anamorphic compensation. Reticle-chuck adjustment mechanisms and substrate-chuck adjustment mechanisms commonly have six degrees-of-freedom capability.

The post-overlay compensation (POC) techniques disclosed herein can be used to achieve better overlay results, thereby producing an increased yield. The POC techniques can be implemented, at least partially, as a machine learning (MI) algorithm to determine an optimized overlay-model based, for example, on the metrology-based measurement data and overlay models maintained in a database. The optimized overlay-model is transferred to the lithography tool and used when exposing a panel thereby providing improved overlay results.

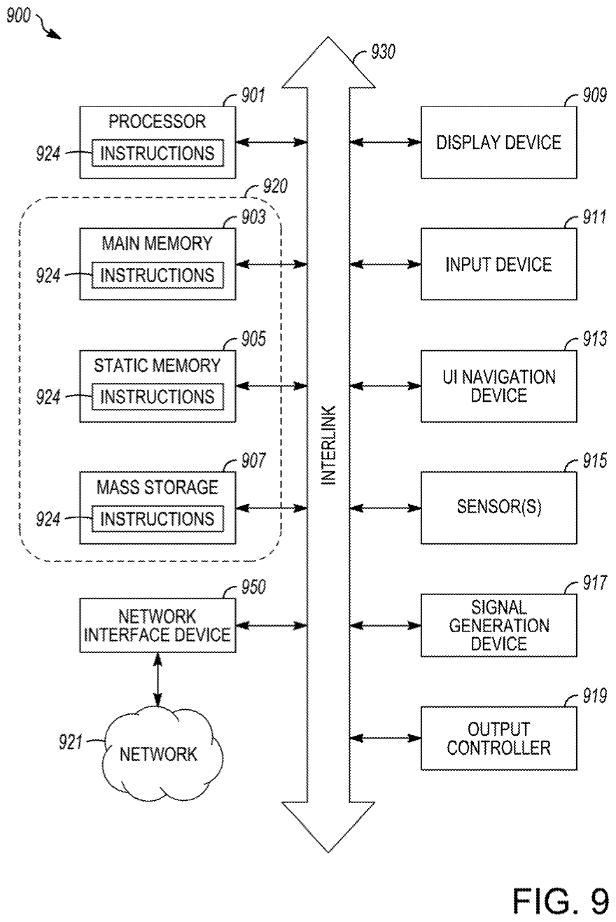

FIG. 9 shows a block diagram of an example comprising a machine upon which any one or more of the techniques (e.g., methodologies) discussed herein may be performed.

The techniques shown and described herein can be performed using a portion or an entirety of a machine 900 as discussed below in relation to FIG. 9. FIG. 9 shows an exemplary block diagram comprising a machine 900 upon which any one or more of the techniques (e.g., methodologies) discussed herein may be performed. In various examples, the machine 900 may operate as a standalone device or may be connected (e.g., networked) to other machines.

In a networked deployment, the machine 900 may operate in the capacity of a server machine, a client machine, or both in server-client network environments. In an example, the machine 900 may act as a peer machine in peer-to-peer (P2P) (or other distributed) network environment. The machine 900 may be a personal computer (PC), a tablet device, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic or a number of components, or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware comprising the circuitry may include variably connected physical components (e.g., execution units, transistors, simple circuits, etc.) including a computer-readable medium physically modified (e.g., magnetically, electrically, such as via a change in physical state or transformation of another physical characteristic, etc.) to encode instructions of the specific operation. In connecting the physical components, the underlying electrical properties of a hardware constituent may be changed, for example, from an insulating characteristic to a conductive characteristic or vice versa. The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine 900 (e.g., computer system) may include a hardware-based processor 901 (e.g., a central processing unit (CPU), a graphics processing unit (GPU), a hardware processor core, or any combination thereof), a main memory 903 and a static memory 905, some or all of which may communicate with each other via an interlink 930 (e.g., a bus). The machine 900 may further include a display device 909, an input device 911 (e.g., an alphanumeric keyboard), and a user interface (UI) navigation device 913 (e.g., a mouse). In an example, the display device 909, the input device 911, and the UI navigation device 913 may comprise at least portions of a touch screen display. The machine 900 may additionally include a storage device 920 (e.g., a drive unit), a signal generation device 917 (e.g., a speaker), a network interface device 950, and one or more sensors 915, such as a global positioning system (GPS) sensor, compass, accelerometer, or other sensor. The machine 900 may include an output controller 919, such as a serial controller or interface (e.g., a universal serial bus (USB)), a parallel controller or interface, or other wired or wireless (e.g., infrared (IR) controllers or interfaces, near field communication (NFC), etc., coupled to communicate or control one or more peripheral devices (e.g., a printer, a card reader, etc.).

The storage device 920 may include a machine readable medium on which is stored one or more sets of data structures or instructions 924 (e.g., software or firmware) embodying or utilized by any one or more of the techniques or functions described herein. The instructions 924 may also reside, completely or at least partially, within a main memory 903, within a static memory 905, within a mass storage device 907, or within the hardware-based processor 901 during execution thereof by the machine 900. In an example, one or any combination of the hardware-based processor 901, the main memory 903, the static memory 905, or the storage device 920 may constitute machine readable media.

While the machine readable medium is considered as a single medium, the term “machine readable medium” may include a single medium or multiple media (e.g., a centralized or distributed database, and/or associated caches and servers) configured to store the one or more instructions 924.

The term “machine readable medium” may include any medium that is capable of storing, encoding, or carrying instructions for execution by the machine 900 and that cause the machine 900 to perform any one or more of the techniques of the present disclosure, or that is capable of storing, encoding or carrying data structures used by or associated with such instructions. Non-limiting machine-readable medium examples may include solid-state memories, and optical and magnetic media. Accordingly, machine-readable media are not transitory propagating signals. Specific examples of massed machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic or other phase-change or state-change memory circuits; magnetic disks, such as internal hard disks and removable disks; magneto-optical disks; and CD-ROM and DVD-ROM disks.

The instructions 924 may further be transmitted or received over a communications network 921 using a transmission medium via the network interface device 950 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., the Institute of Electrical and Electronics Engineers (IEEE) 802.22 family of standards known as Wi-Fi®, the IEEE 802.26 family of standards known as WiMax®), the IEEE 802.25.4 family of standards, peer-to-peer (P2P) networks, among others. In an example, the network interface device 950 may include one or more physical jacks (e.g., Ethernet, coaxial, or phone jacks) or one or more antennas to connect to the communications network 926. In an example, the network interface device 950 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 900, and includes digital or analog communications signals or other intangible medium to facilitate communication of such software.

As used herein, the term “or” may be construed in an inclusive or exclusive sense. Further, other embodiments will be understood by a person of ordinary skill in the art based upon reading and understanding the disclosure provided. Moreover, the person of ordinary skill in the art will readily understand that various combinations of the techniques and examples provided herein may all be applied in various combinations.

Throughout this specification, plural instances may implement components, operations, or structures described as a single instance. Although individual operations are illustrated and described as separate operations, one or more of the individual operations may be performed concurrently, and, unless otherwise stated, nothing requires that the operations necessarily be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter described herein.

Further, although not shown explicitly but understandable to a skilled artisan, each of the various arrangements, quantities, and number of elements may be varied (e.g., the number of cameras). Moreover, each of the examples shown and described herein is merely representative of one possible configuration and should not be taken as limiting the scope of the disclosure.

Although various embodiments are discussed separately, these separate embodiments are not intended to be considered as independent techniques or designs. As indicated above, each of the various portions may be inter-related and each may be used separately or in combination with other embodiments discussed herein. For example, although various embodiments of operations, systems, and processes have been described, these methods, operations, systems, and processes may be used either separately or in various combinations.

Consequently, many modifications and variations can be made, as will be apparent to a person of ordinary skill in the art upon reading and understanding the disclosure provided herein. Functionally equivalent methods and devices within the scope of the disclosure, in addition to those enumerated herein, will be apparent to the skilled artisan from the foregoing descriptions. Portions and features of some embodiments may be included in, or substituted for, those of others. Such modifications and variations are intended to fall within a scope of the appended claims. Therefore, the present disclosure is to be limited only by the terms of the appended claims, along with the full scope of equivalents to which such claims are entitled. It is also to be understood that the terminology used herein is for the purpose of describing particular embodiments only and is not intended to be limiting.

The Abstract of the Disclosure is provided to allow the reader to ascertain quickly the nature of the technical disclosure. The abstract is submitted with the understanding that it will not be used to interpret or limit the claims. In addition, in the foregoing Detailed Description, it may be seen that various features may be grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

The description provided herein includes illustrative examples, devices, and apparatuses that embody various aspects of the matter described in this document. In the description, for purposes of explanation, numerous specific details are set forth in order to provide an understanding of various embodiments of the matter discussed. It will be evident however, to those of ordinary skill in the art, that various embodiments of the disclosed subject matter may be practiced without these specific details. Further, well-known structures, materials, and techniques have not been shown in detail, so as not to obscure the various illustrated embodiments. As used herein, the terms “about,” “approximately,” and “substantially” may refer to values that are, for example, within ±10% of a given value or range of values.

### The Following Numbered Examples are Specific Embodiments of the Disclosed Subject Matter

Example 1: In various embodiments, the disclosed subject matter is a method for analyzing and correcting for pattern distortion in a panel during a lithography operation on the panel. The method includes determining an optical model to be applied to correct for distortion in the panel. The determination of the optical model includes making a determination of potential differences when exposing on the panel in at least one of magnification correction and anamorphic correction from a number of patterns on a reticle as compared with planned features on respective ones of the number of patterns. The at least one of the magnification correction and the anamorphic correction to be applied to an exposure field during a photolithographic exposure on the panel. The method further includes determining correction data from the determined optical model for applying to the lithography operation and applying the correction data to a global zone of the exposure field. The correction data within the global zone including corrections from each of the number of patterns on the reticle within the exposure field. The exposure field is then photolithographically exposed by the lithography tool in a single shot.

Example 2: The method of Example 1, wherein the magnification correction comprises an optical correction used to change isotropically an apparent size of original patterns on the reticle to correct for magnification distortion errors caused by the panel distortion.

Example 3: The method of either Example 1 or Example 2, wherein the anamorphic correction comprises an optical correction used to change anisotropically at least one of an apparent size and a shape of original patterns on the reticle to correct for anamorphic distortion errors caused by the panel distortion.

Example 4: The method of any one of the previous Examples, wherein the determination of the optical model is performed by collecting metrology-based measurement data from the panel, the metrology-based measurement data including comparing alignment data supplied by a lithography tool used to expose the panel, making a determination of measured potential differences in at least one of magnification correction and anamorphic correction from a plurality of patterns on the reticle as compared with measurements of planned features on respective ones of the plurality of patterns, the at least one of magnification correction and anamorphic correction to be applied optically to an exposure field during a photolithographic exposure.

Example 5: The method of any one of the previous Examples, wherein the determination of the optical model is performed based on collected data from similar processes used on a panel, the collected data including making a determination of expected errors in an least one of magnification correction and anamorphic correction from a plurality of patterns on a reticle as compared with planned features on respective ones of the plurality of patterns.

Example 6: The method of any one of the previous Examples, wherein the determination of the optical model is based on a post-overlay compensation machine-learning (POC ML) algorithm.

Example 7: The method of any one of the previous Examples, wherein the correction determined from each of the plurality of patterns relates to a respective plurality of die locations.

Example 8: The method of any one of the previous Examples, wherein the determination of differences in at least one of magnification correction and anamorphic correction from the plurality of patterns on a reticle as compared with planned features on respective ones of the plurality of patterns, is combined to produce global corrections to be applied to an optical system of a photolithography tool.

Example 9: The method of any one of the previous Examples, further comprising preparing a vector field for each of the plurality of the differences in at least one of the magnification correction and the anamorphic correction from the plurality of patterns on the reticle.

Example 10: The method of any one of the previous Examples, wherein corrections in the magnification correction can be selected from corrections including translational corrections, rotational corrections, scaling corrections, and orthogonality corrections.

Example 11: The method of any one of the previous Examples, wherein corrections in the anamorphic correction can be selected from corrections including translational corrections, rotational corrections, magnification corrections, radial-distortion corrections, scaling corrections, and trapezoidal corrections.

Example 12: The method of any one of the previous Examples, wherein the exposure field exposed in the single shot is selected to have dimensions of at least 250 mm by 250 mm.

Example 13: In various embodiments, the disclosed subject matter is a system to analyze and correct for pattern distortion in a panel during a lithography operation on the panel. The system includes one or more hardware-based computational engines to determine an optical model to be applied to correct for distortion in the panel. The determination of the optical model includes collecting metrology-based measurement data from the panel, comparing alignment data supplied by a lithography tool used to expose the panel, and making a determination of measured potential differences in at least one of magnification correction and anamorphic correction from a number of patterns on the reticle as compared with measurements of planned features on respective ones of the number of patterns. The at least one of magnification correction and anamorphic correction to be applied optically to an exposure field during a photolithographic exposure. Correction data are determined from the determined optical model to apply to the lithography operation. A memory is coupled to the one or more hardware-based computational engines to store results from the determination of the optical model. The lithography tool is to apply the correction data received from the memory to a global zone within the exposure field where the correction data within the global zone includes corrections from each of the number of patterns on the reticle within the exposure field. The lithography tool photolithographically exposes the exposure field in a single shot.

Example 14: The system of Example 13, wherein the lithography tool is to apply a magnification correction, the magnification correction comprising an optical correction used to change isotropically an apparent size of original patterns on the reticle to correct for magnification distortion errors caused by the panel distortion.

Example 15: The system of either Example 13 or Example 14, wherein the lithography tool is to apply an anamorphic correction, the anamorphic correction comprising an optical correction used to change anisotropically at least one of an apparent size and a shape of original patterns on the reticle to correct for anamorphic distortion errors caused by the panel distortion.

Example 16: The system of any one of Example 13 through Example 15, wherein the adjustment of the lithography tool can include adjusting at least one of a reticle stage relative to an optical system of the lithography tool, adjusting the reticle stage relative to a substrate stage of the lithography tool, and adjusting the optical system of the photolithography tool relative to the substrate stage.

Example 17: In various embodiments, the disclosed subject matter is a method for analyzing and correcting for pattern distortion in a panel during a lithography operation on the panel, the method includes determining an optical model to be applied to correct for distortion in the panel. The determination of the optical model includes collecting metrology-based measurement data from the panel, comparing alignment data supplied by a lithography tool used to expose the panel, making a determination of measured potential differences in at least one of magnification correction and anamorphic correction from a number of patterns on the reticle as compared with measurements of planned features on respective ones of the number of patterns. The at least one of magnification correction and anamorphic correction to be applied optically to an exposure field during a photolithographic exposure. The method further includes determining correction data from the determined optical model to apply to the lithography operation and applying the correction data to a global zone within the exposure field. The correction data within the global zone including corrections from each of the number of patterns on the reticle within the exposure field. The exposure field is then photolithographically exposed by the lithography tool in a single shot.

Example 18: In various embodiments, the disclosed subject matter is a machine-readable medium including instructions that, when executed by one or more processors of a machine, cause the machine to perform operations. The operations include determining an optical model to be applied to correct for distortion in the panel. The determination of the optical model includes making a determination of potential differences when exposing on the panel in at least one of magnification correction and anamorphic correction from a number of patterns on a reticle as compared with planned features on respective ones of the number of patterns. The at least one of the magnification correction and the anamorphic correction to be applied to an exposure field during a photolithographic exposure on the panel. The method further includes determining correction data from the determined optical model for applying to the lithography operation and applying the correction data to a global zone of the exposure field. The correction data within the global zone including corrections from each of the number of patterns on the reticle within the exposure field. The exposure field is then photolithographically exposed by the lithography tool in a single shot.

Example 19: The machine-readable medium of Example 18, wherein the determination of the optical model is performed by collecting metrology-based measurement data from the panel, the metrology-based measurement data including comparing alignment data supplied by a lithography tool used to expose the panel; and making a determination of measured potential differences in at least one of magnification correction and anamorphic correction from a plurality of patterns on the reticle as compared with measurements of planned features on respective ones of the plurality of patterns, the at least one of magnification correction and anamorphic correction to be applied optically to an exposure field during a photolithographic exposure.

Example 20: The machine-readable medium of either Example 18 or Example 19, wherein the determination of the optical model is performed based on collected data from similar processes used on a panel, the collected data including making a determination of expected errors in an least one of magnification correction and anamorphic correction from a plurality of patterns on a reticle as compared with planned features on respective ones of the plurality of patterns.

Example 21: The machine-readable medium of any one of Examples 18 through Example 20, wherein the determination of the optical model is based on a post-overlay compensation machine-learning (POC ML) algorithm.

1. A method for analyzing and correcting for pattern distortion in a panel during a lithography operation on the panel, the method comprising:
determining an optical model to be applied to correct for distortion in the panel, the determination of the optical model including making a determination of potential differences when exposing on the panel in at least one of magnification correction and anamorphic correction from a plurality of patterns on a reticle as compared with planned features on respective ones of the plurality of patterns, the at least one of the magnification correction and the anamorphic correction to be applied to an exposure field during a photolithographic exposure on the panel;
determining correction data from the determined optical model for applying to the lithography operation;
applying the correction data to a global zone of the exposure field, the correction data within the global zone including corrections from each of the plurality of patterns on the reticle within the exposure field; and
photolithographically exposing the exposure field in a single shot.

2. The method claim 1, wherein the magnification correction comprises an optical correction used to change isotropically an apparent size of original patterns on the reticle to correct for magnification distortion errors caused by the panel distortion.

3. The method of claim 1, wherein the anamorphic correction comprises an optical correction used to change anisotropically at least one of an apparent size and a shape of original patterns on the reticle to correct for anamorphic distortion errors caused by the panel distortion.

4. The method of claim 1, wherein the determination of the optical model is performed by collecting metrology-based measurement data from the panel, the metrology-based measurement data including:
comparing alignment data supplied by a lithography tool used to expose the panel;
making a determination of measured potential differences in at least one of magnification correction and anamorphic correction from a plurality of patterns on the reticle as compared with measurements of planned features on respective ones of the plurality of patterns, the at least one of magnification correction and anamorphic correction to be applied optically to an exposure field during a photolithographic exposure.

5. The method of claim 1, wherein the determination of the optical model is performed based on collected data from similar processes used on a panel, the collected data including making a determination of expected errors in an least one of magnification correction and anamorphic correction from a plurality of patterns on a reticle as compared with planned features on respective ones of the plurality of patterns.

6. The method of claim 5, wherein the determination of the optical model is based on a post-overlay compensation machine-learning (POC ML) algorithm.

7. The method of claim 1, wherein the correction determined from each of the plurality of patterns relates to a respective plurality of die locations.

8. The method of claim 1, wherein the determination of differences in at least one of magnification correction and anamorphic correction from the plurality of patterns on a reticle as compared with planned features on respective ones of the plurality of patterns, is combined to produce global corrections to be applied to an optical system of a photolithography tool.

9. The method of claim 1, further comprising preparing a vector field for each of the plurality of the differences in at least one of the magnification correction and the anamorphic correction from the plurality of patterns on the reticle.

10. The method of claim 1, wherein corrections in the magnification correction can be selected from corrections including translational corrections, rotational corrections, scaling corrections, and orthogonality corrections.

11. The method of claim 1, wherein corrections in the anamorphic correction can be selected from corrections including translational corrections, rotational corrections, magnification corrections, radial-distortion corrections, scaling corrections, and trapezoidal corrections.

12. The method of claim 1, wherein the exposure field exposed in the single shot is selected to have dimensions of at least 250 mm by 250 mm.

13. A system to analyze and correct for pattern distortion in a panel during a lithography operation on the panel, the system comprising:
one or more hardware-based computational engines to determine an optical model to be applied to correct for distortion in the panel, the determination of the optical model including:
collecting metrology-based measurement data from the panel;
comparing alignment data supplied by a lithography tool used to expose the panel;
making a determination of measured potential differences in at least one of magnification correction and anamorphic correction from a plurality of patterns on the reticle as compared with measurements of planned features on respective ones of the plurality of patterns, the at least one of magnification correction and anamorphic correction to be applied optically to an exposure field during a photolithographic exposure; and
determining correction data from the determined optical model to apply to the lithography operation;
a memory coupled to the one or more hardware-based computational engines to store results from the determination of the optical model;
the lithography tool to apply the correction data received from the memory to a global zone within the exposure field, the correction data within the global zone including corrections from each of the plurality of patterns on the reticle within the exposure field; and
the lithography tool to photolithographically expose the exposure field in a single shot.

14. The system claim 13, wherein the lithography tool is to apply a magnification correction, the magnification correction comprising an optical correction used to change isotropically an apparent size of original patterns on the reticle to correct for magnification distortion errors caused by the panel distortion.

15. The system claim 13, wherein the lithography tool is to apply an anamorphic correction, the anamorphic correction comprising an optical correction used to change anisotropically at least one of an apparent size and a shape of original patterns on the reticle to correct for anamorphic distortion errors caused by the panel distortion.

16. The system of claim 14, wherein the adjustment of the lithography tool can include adjusting at least one of a reticle stage relative to an optical system of the lithography tool, adjusting the reticle stage relative to a substrate stage of the lithography tool, and adjusting the optical system of the photolithography tool relative to the substrate stage.

17. A machine-readable medium comprising instructions that, when executed by one or more processors of a machine, cause the machine to perform operations comprising:
determining an optical model to be applied to correct for distortion in the panel, the determination of the optical model including making a determination of potential differences when exposing on the panel in at least one of magnification correction and anamorphic correction from a plurality of patterns on a reticle as compared with planned features on respective ones of the plurality of patterns, the at least one of the magnification correction and the anamorphic correction to be applied to an exposure field during a photolithographic exposure on the panel;
determining correction data from the determined optical model for applying to the lithography operation;
applying the correction data to a global zone of the exposure field, the correction data within the global zone including corrections from each of the plurality of patterns on the reticle within the exposure field; and
photolithographically exposing the exposure field in a single shot.

18. The machine-readable medium of claim 17, wherein the determination of the optical model is performed by collecting metrology-based measurement data from the panel, the metrology-based measurement data including:
comparing alignment data supplied by a lithography tool used to expose the panel; and
making a determination of measured potential differences in at least one of magnification correction and anamorphic correction from a plurality of patterns on the reticle as compared with measurements of planned features on respective ones of the plurality of patterns, the at least one of magnification correction and anamorphic correction to be applied optically to an exposure field during a photolithographic exposure.

19. The machine-readable medium of claim 18, wherein the determination of the optical model is performed based on collected data from similar processes used on a panel, the collected data including making a determination of expected errors in an least one of magnification correction and anamorphic correction from a plurality of patterns on a reticle as compared with planned features on respective ones of the plurality of patterns.

20. The machine-readable medium of claim 19, wherein the determination of the optical model is based on a post-overlay compensation machine-learning (POC ML) algorithm.

21. The system of claim 15, wherein the adjustment of the lithography tool can include adjusting at least one of a reticle stage relative to an optical system of the lithography tool, adjusting the reticle stage relative to a substrate stage of the lithography tool, and adjusting the optical system of the photolithography tool relative to the substrate stage.
